(19) United States
(12) Patent Application Publication
(10) Pub. No.: US 2025/0291246 A1
(43) Pub. Date: Sep. 18, 2025

(54) POLYSILOXANE COMPOSITION

(71) Applicant: Merck Patent GmbH, Darmstadt (DE)

(72) Inventors: Yuki Ozaki, Shizuoka (JP); Atsuhiko Sato, Shizuoka (JP)

(21) Appl. No.: 19/222,373

(22) Filed: May 29, 2025

Related U.S. Application Data
(63) Continuation of application No. PCT/EP2023/083550, filed on Nov. 29, 2023.

(30) Foreign Application Priority Data
Dec. 2, 2022 (JP) 2022-193704

(51) Int. Cl. G03F 7/004; G03F 7/075; G03F 7/11; G03F 7/20; G03F 7/38

(52) U.S. Cl. CPC G03F 7/0043; G03F 7/0048; G03F 7/0752; G03F 7/11; G03F 7/2014; G03F 7/38

(57) ABSTRACT

A polysiloxane composition having a repeating unit represented by the following formula (Ia) as defined herein is used to improve the exposure sensitivity of a metal oxide resist.

### CROSS-REFERENCE TO RELATED APPLICATIONS

This application is a Continuation under 35 USC § 111 (a) of International Patent Application No. PCT/EP2023/083550 filed Nov. 29, 2023, which claims priority to the JP Application no. 2022-193704 filed Dec. 2, 2022. The entire contents of these applications are incorporated herein by reference in their entirety.

### BACKGROUND OF THE INVENTION

### Field of the Invention

The present invention relates to use of a polysiloxane composition. Further, the present invention relates to a metal oxide resist underlayer composition, a method for manufacturing a film using the same, a film using the same, and a method for manufacturing an electronic device comprising the film.

### Background Art

In the process of manufacturing a device such as a semiconductor, microfabrication by a lithography technique using a photoresist is generally performed. The wavelength used for exposure has been shortened, and a lithography technique using extreme ultraviolet ray (EUV) having a wavelength of 13.5 nm has been studied.

Under conventional exposure conditions of wavelengths of 248 nm and 193 nm, a chemically amplified resist composition is used as a resist material. Various resist materials have been considered in the case of using EUV, one of which is a metal oxide resist (MOR).

As an EUV resist underlayer forming composition, a composition containing a silane having a certain structure has been proposed as disclosed in WO 2013/051558 A.

### SUMMARY OF THE INVENTION

### Problems to be Solved by the Invention

The present inventors considered that there are one or more problems still in need of improvements. These problems are, for example, as follows:

The exposure sensitivity of the metal oxide resist is low; the adhesion between the metal oxide resist and a base film is low; etching selectivity between the metal oxide resist and the base film is low; there are numerous defects generated in the step of using the metal oxide; and the process window of the step using the metal oxide resist is narrow.

### Means for Solving the Problems

The present invention relates to a method of using a composition that includes a polysiloxane including a repeating unit represented by the following formula (Ia) to improve the exposure sensitivity of a metal oxide resist:

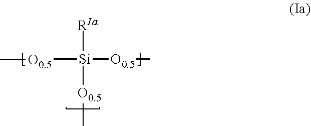

wherein,
R^{Ia} is phenyl, naphthyl, phenalenyl, phenanthrenyl or anthracenyl, which is unsubstituted or substituted with C₁₋₅ alkyl.

The present invention also relates to a metal oxide resist underlayer composition that includes a polysiloxane including a repeating unit represented by the formula (Ia) and a solvent:

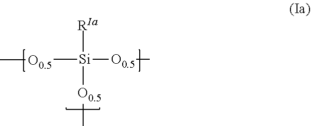

wherein,
R^{Ia} is phenyl, naphthyl, phenalenyl, phenanthrenyl or anthracenyl, which is unsubstituted or substituted with C₁-5 alkyl.

The present invention also relates to a method for manufacturing a metal oxide resist film including the following steps:
(a) applying the above-mentioned composition above a substrate to form a metal oxide resist underlayer;
(b) irradiating the metal oxide resist underlayer with the energy ray; and
(c) forming a metal oxide resist film above the metal oxide resist underlayer irradiated with the energy ray.

The present invention also relates to a method for manufacturing an electronic device according to the present invention including the above-mentioned method for manufacturing a resist film.

### Effects of the Invention

According to the present invention, it is possible to expect one or more of the following effects.

The exposure sensitivity of the metal oxide resist is sufficient; the adhesion between the metal oxide resist and a base film is sufficient; etching selectivity between the metal oxide resist and the base film is sufficient; defects generated in the step using the metal oxide resist is suppressed; and the process window of the step using the metal oxide resist is sufficient.

### DETAILED DESCRIPTION OF THE INVENTION

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plurality of types of repeating units, these repeating units copolymerize. Copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as a solvent or another component.

Hereinafter, embodiments of the present invention are described in detail.

### Method of Using Composition Containing Polysiloxane

The present invention provides a method of using a composition containing a polysiloxane including repeating units represented by the following formula (Ia) to improve the exposure sensitivity of a metal oxide resist. The metal oxide resist is more preferably an organometallic oxide hydroxide-containing resist, and those described in JP 2021-73367 A can be used. The metal oxide resist is preferably an EUV resist, and in a preferred embodiment, the metal oxide resist is a negative resist.

The composition containing a polysiloxane is used, for example, for forming a lower layer of the metal oxide resist, preferably applied above an organic film such as SOC (Spin on Carbon) formed above a substrate and used for forming a film. In a preferred embodiment, a film is formed immediately above an SOC film using the composition containing a polysiloxane, and a metal oxide resist film is formed immediately above the film.

The composition containing a polysiloxane preferably further includes a solvent. The content of the solvent is preferably 90.0 to 99.9 mass % based on the total mass of the composition. The composition that includes a polysiloxane can also contain components other than the solvent. The solvent and other components that can be used are the same as those described in the following metal oxide resist underlayer composition.

### Polysiloxane

The polysiloxane used in the present invention comprises a repeating unit represented by the formula (Ia).

It is considered that when the polysiloxane comprises the repeating unit represented by the formula (Ia), the exposure sensitivity of the metal oxide resist is improved. This is not bound by theory, but for example, after the composition containing a polysiloxane forms a film, desorption by light irradiation or the like is likely to occur since the R^{Ia} group in the formula (Ia) has a certain structure having an aromatic ring. By the desorption, a hydroxy group is generated on the film surface, and in particular, when the metal oxide resist film is immediately above the film surface, adhesion between the films is increased. It is considered that the exposure sensitivity is improved by the improvement of the adhesion.

Since the R^{Ia} group is a bulky group having an aromatic ring, the elastic modulus of the film formed using the polysiloxane is suppressed, so that there is also an effect of suppressing peeling from the metal oxide resist film.

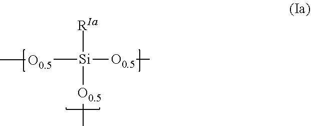

wherein,
R^{Ia} is phenyl, naphthyl, phenalenyl, phenanthrenyl or anthracenyl, which is unsubstituted or substituted with C₁₋₅ alkyl, preferably unsubstituted phenyl, naphthyl, phenalenyl, phenanthrenyl or anthracenyl, more preferably phenyl or naphthyl. It is further preferable that R^{Ia} is phenyl because the solubility of polysiloxane in the solvent is increased and the cured film becomes less likely to crack.

The number of the repeating units represented by the formula (Ia) is preferably 5 to 100%, more preferably 10 to 100%, further preferably 15 to 90%, further more preferably 30 to 700%, based on the total number of the repeating units contained in the polysiloxane molecule.

Preferably, the polysiloxane used in the present invention further comprises a repeating unit represented by the following formula (Ib):

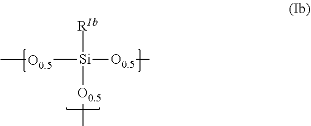

wherein,
R^{Ib} is C₁₋₆ alkyl, preferably linear or branched C₁₋₅ alkyl, more preferably methyl, ethyl, propyl, or butyl. It is further preferable that R¹ is methyl because the film hardness after curing is increased and chemical resistance is increased.

The number of the repeating units represented by the formula (Ib) is preferably 5 to 90%, more preferably 20 to 80%, further preferably 30 to 70%, based on the total number of the repeating units contained in the polysiloxane molecule.

The polysiloxane used in the present invention may further comprise a repeating unit represented by the formula (Ic):

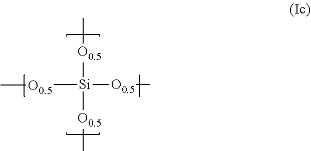

The number of the repeating units represented by the formula (Ic) is preferably 0 to 10%, more preferably 0 to 5%, further preferably 0 to 1%, based on the total number of the repeating units contained in the polysiloxane molecule. In a preferred embodiment, the polysiloxane used in the present invention does not comprise the repeating unit represented by the formula (Ic) (0%).

In the repeating unit represented by the formula (Ic), the desorption of a substituent by light irradiation or the like after film formation does not occur, and thus a phenomenon of generating a hydroxy group does not occur. Therefore, it is considered that this does not contribute to the improvement of the exposure sensitivity as occurs in the case of including the repeating unit represented by the formula (Ia).

When the repeating unit represented by the formula (Ic) is included, the film has a high elastic modulus and is rigid, so that peeling between the film including the repeating unit represented by the formula (Ic) and another film (for example, a metal oxide resist film) tends to easily occur.

The polysiloxane used in the present invention may comprise a repeating unit other than the above, but the number thereof is preferably 20% or less, more preferably 10% or less, based on the total number of the repeating units contained in the polysiloxane molecule. It is also a preferred embodiment of the present invention that it contains no repeating unit other than the above.

Examples of the repeating unit other than the above include monovalent groups such as hydrogen, fluoroalkyl, fluoroaryl, a nitrogen-containing group, and an oxygen-containing group as a group corresponding to R^{Ib} of the formula (Ib). This group may be divalent or trivalent, and in this case, this group connects each Si contained in a plurality of repeating units.

The polysiloxane used in the present invention preferably has silanol at the end. Here, silanol means one in which an OH group is directly bonded to a Si skeleton, and it is one in which hydroxy is directly bonded to a silicon atom in a polysiloxane containing the above-mentioned repeating unit or the like. That is, silanol is formed by binding —O_{0.5}H with —O_{0.5}— of the above formula. The content of silanol in the polysiloxane varies depending on the synthesis conditions of the polysiloxane, for example, the mixing ratio of the monomers and the type of the reaction catalyst.

The mass average molecular weight of the polysiloxane used in the present invention is preferably 500 to 20,000, more preferably 800 to 15,000, further preferably 1,000 to 10,000. Here, the mass average molecular weight is a mass average molecular weight in terms of polystyrene, which can be measured by the gel permeation chromatography based on polystyrene.

### Metal Oxide Resist Underlayer Composition

A metal oxide resist underlayer composition according to the present invention (hereinafter sometimes referred to as the underlayer composition) contains
a polysiloxane comprising repeating units represented by the formula (Ia) and a solvent. Hereinafter, each component contained in the underlayer composition is described in detail.

### Polysiloxane

The polysiloxane used in the underlayer composition according to the present invention is as described above.

The content of the polysiloxane is preferably 0.10 to 10.0 mass %, more preferably 0.10 to 5.0 mass %, further preferably 0.10 to 3.0 mass %, based on the total mass of the composition.

### Solvent

The solvent is not particularly limited as long as it uniformly dissolves or disperses the above-mentioned polysiloxane and additives added as needed.

Examples of the solvent that can be used in the present invention include ethylene glycol monoalkyl ethers such as ethylene glycol monomethyl ether, ethylene glycol monoethyl ether, ethylene glycol monopropyl ether and ethylene glycol monobutyl ether; diethylene glycol dialkyl ethers such as diethylene glycol dimethyl ether, diethylene glycol diethyl ether, diethylene glycol dipropyl ether and diethylene glycol dibutyl ether; ethylene glycol alkyl ether acetates such as methyl cellosolve acetate, ethyl cellosolve acetate; propylene glycol monoalkyl ethers such as propylene glycol monomethyl ether (PGME) and propylene glycol monoethyl ether; propylene glycol alkyl ether acetates such as propylene glycol monomethyl ether acetate (PGMEA), propylene glycol monoethyl ether acetate and propylene glycol monopropyl ether acetate; aromatic hydrocarbons such as benzene, toluene and xylene; ketones such as methyl ethyl ketone, acetone, methyl amyl ketone, methyl isobutyl ketone and cyclohexanone; alcohols such as ethanol, propanol, butanol, hexanol, cyclohexanol, ethylene glycol, glycerin, 3-methoxybutanol and 1,3-butanediol; esters such as ethyl lactate, butyl acetate, 3-methoxybutyl acetate, ethyl 3-ethoxy-propionate and methyl 3-methoxypropionate; and cyclic esters such as γ-butyrolactone, and preferably at least one selected from the group consisting of propylene glycol monomethyl ether, 3-methoxybutanol, 1,3-butanediol, propylene glycol monomethyl ether acetate, ethyl lactate, butyl acetate, and 3-methoxybutyl acetate. The solvent may be used alone or in combination of two or more of any of these.

The content of the solvent is preferably 90.0 to 99.9 mass %, more preferably 95.0 to 99.9 mass %, further preferably 97.0 to 99.9 mass %, based on the total mass of the composition according to the present invention.

### Ionic Liquid

The underlayer composition according to the present invention can contain an ionic liquid.

The ionic liquid is a salt that exists as a liquid in a wide temperature range, and is a liquid consisting only of ions. Generally, a salt having a melting point of 100° C. or lower is defined as an ionic liquid. The ionic liquid used in the present invention has a melting point of 100° C. or lower, preferably 80° C. or lower, more preferably 60° C. or lower, further preferably 30° C. or lower.

The ionic liquid used in the present invention is preferably a basic ionic liquid, preferably one composed of a combination of a strong base and a weak acid.

The cation of the ionic liquid is preferably at least one cation selected from the group consisting of an imidazolium type ion, a pyrrolidinium type ion, a piperidinium type ion, a pyridinium type ion, and an ammonium type ion, and more preferably an imidazolium type ion.

The imidazolium type ion is preferably represented by the following formula (A):

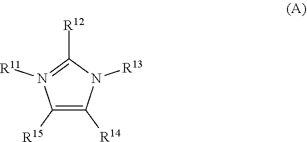

wherein,
R¹¹, R¹², R¹³, R¹⁴ and R¹⁵ are each independently hydrogen, linear or branched C₁₋₁₈ alkyl, cyclic C₅₋₁₂ alkyl, or C₆₋₁₄ aryl.

Exemplified embodiments of the imidazolium type ion include 1-methylimidazolium, 1-methyl-2-ethylimidazolium, 1-methyl-3-octylimidazolium, 1,2-dimethylimidazolium, 1,3-dimethylimidazolium, 2,3-dimethylimidazolium, 3,4-dimethylimidazolium, 1,2,3-trimethylimidazolium, 1,3,4-trimethylimidazolium, 1,3,4,5-tetramethylimidazolium, 1-ethylimidazolium, 1-ethyl-2-methyl imidazolium, 1-ethyl-3-methylimidazolium, 1-ethyl-2,3-dimethylimidazolium, 2-ethyl-3,4-dimethylimidazolium, 1-propyl imidazolium, 1-propyl-2-methyl imidazolium, 1-propyl-3-methylimidazolium, 1-propyl-2,3-dimethylimidazolium, 1,3-dipropylimidazolium, 1-butylimidazolium, 1-butyl-2-methylimidazolium, 1-butyl-3-methylimidazolium, 1-butyl-4-methylimidazolium, 1-butyl-2,3-dimethylimidazolium, 1-butyl-3,4-dimethylimidazolium, 1-butyl-3,4,5-trimethylimidazolium, 1-butyl-2-ethylimidazolium, 1-butyl-3-ethylimidazolium, 1-butyl-2-ethyl-5-methylimidazolium, 1,3-dibutylimidazolium, 1,3-dibutyl-2-methylimidazolium, 1-pentylimidazolium, 1-pentyl-2-methylimidazolium, 1-pentyl-3-methyl imidazolium, 1-pentyl-2,3-dimethylimidazolium, 1-hexylimidazolium, 1-hexyl-2-methylimidazolium, 1-hexyl-3-methylimidazolium, 1-hexyl-2,3-dimethylimidazolium, 1-octyl-2-methylimidazolium, 1-octyl-3-methylimidazolium, 1-decyl-3-methylimidazolium, 1-dodecyl-3-methylimidazolium, 1-tetradecyl-3-methylimidazolium, 1-hexadecyl-3-methylimidazolium and 1-benzyl-3-methylimidazolium, and preferably 1-ethyl-3-methylimidazolium, 1-ethyl-2,3-dimethylimidazolium, 1,3-dimethylimidazolium, 1,2,3-trimethylimidazolium, 1-propyl-3-methylimidazolium, 1-propyl-2,3-dimethylimidazolium, 1-butyl-3-methylimidazolium, 1-butyl-2,3-dimethylimidazolium and 1-octyl-3-methylimidazolium.

The pyrrolidinium type ion is preferably represented by the following formula (B):

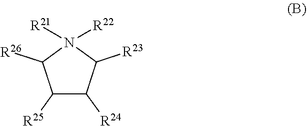

wherein,
R²¹, R₂₂, R²³, R²⁴, R²⁵ and R²⁶ are each independently hydrogen, linear or branched C₁₋₁₈ alkyl, cyclic C₅₋₁₂ alkyl, or C₆₋₁₄ aryl.

Exemplified embodiments of the pyrrolidinium type ion include 1-methyl-1-ethylpyrrolidinium, 1-methyl-1-propylpyrrolidinium, 1-methyl-1-butylpyrrolidinium, 1-methyl-1-pentylpyrrolidinium, 1-methyl-1-hexylpyrrolidinium and 1-methyl-1-octylpyrrolidinium, and preferably 1-methyl-1-propylpyrrolidinium.

The piperidinium type ion is preferably represented by the following formula (C):

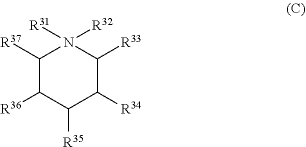

wherein,
R³¹, R³², R₃₃, R³⁴, R³⁵, R³⁶ and R³⁷ are each independently hydrogen, linear or branched C₁₋₁₈ alkyl, cyclic C₅₋₁₂ alkyl, or C₆₋₁₄ aryl.

Exemplified embodiments of the piperidinium type ion include 1-methyl-1-ethylpiperidinium, 1-methyl-1-propylpiperidinium, 1-methyl-1-butylpiperidinium, 1-methyl-1-pentylpiperidinium, 1-methyl-1-hexylpiperidinium and 1-methyl-1-octylpiperidinium, and preferably 1-methyl-1-butylpiperidinium.

The pyridinium type ion is preferably represented by the following formula (D):

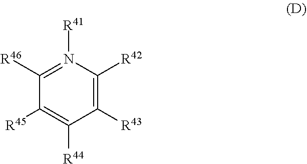

wherein,
R⁴¹, R⁴², R⁴³, R⁴⁴, R⁴⁵ and R⁴⁶ are each independently hydrogen, linear or branched C₁₋₁₈ alkyl, cyclic C₅₋₁₂ alkyl, or C₆₋₁₄ aryl.

Exemplified embodiments of the pyridinium type ion include 1-methylpyridinium, 1-ethylpyridinium, 1-propylpyridinium, 1-butylpyridinium, 1-pentylpyridinium, 1-hexylpyridinium, 1-octylpyridinium, 1-methyl-3-ethylpyridinium, 1-methyl-4-ethylpyridinium, 1-methyl-3-butylpyridinium, 1-methyl-4-butylpyridinium, 1-ethyl-3-methylpyridinium, 1-ethyl-4-methylpyridinium, 1-propyl-3-methylpyridinium, 1-propyl-4-methylpyridinium, 1-butyl-3-methylpyridinium, 1-butyl-4-methylpyridinium, 1-hexyl-4-methylpyridinium and 1-octyl-4-methylpyridinium, and preferably 1-butylpyridinium and 1-ethyl-4-methylpyridinium.

The ammonium type ion is preferably represented by the following formula (E):

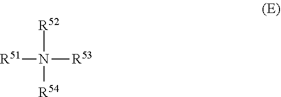

wherein,
R⁵¹, R⁵², R⁵³ and R⁵⁴ are each independently linear or branched C₁₋₁₈ alkyl, linear or branched C₁₋₁₈ hydroxyalkyl, cyclic C₅₋₁₂ alkyl, or C₆₋₁₄ aryl.

Exemplified embodiments of the ammonium type ion include trimethylethylammonium, trimethylbutylammonium, triethylmethylammonium, tripropylmethylammonium, tributylmethylammonium, trihexylmethylammonium, trioctylmethylammonium, tetrabutylammonium, 2-hydroxyethyltrimethylammonium and tris(2-hydroxyethyl)methylammonium, and preferably tetrabutylammonium, tributylmethylammonium and 2-hydroxyethyltrimethylammonium.

The anion of the ionic liquid is preferably at least one anion selected from the group consisting of a formate ion, an acetate ion, a propionate ion, a lactate ion, an oleate ion, a salicylate ion, a dicyanamide ion, a cyanamide ion, a thiocyanate ion, a methyl sulfate ion, an ethyl sulfate ion, a hydrogen sulfate ion, a methane sulfonate ion, a trifluoromethane sulfonate ion, a p-toluene sulfonate ion, a bis(trifluoromethylsulfonyl)imide ion, a bis(fluorosulfonyl)imide ion, a methyl carbonate ion, a hydrogen carbonate ion, a diethyl phosphate ion, a dibutyl phosphate ion, a hexafluorophosphate ion, a tetrafluoroborate ion, a chlorine ion and a bromine ion, and more preferably an acetate ion, a dicyanamide ion, a cyanamide ion, a chlorine ion and a bromine ion.

In a preferred embodiment, exemplified embodiments of the ionic liquid include trimethylbutylammonium bis(trifluoromethylsulfonyl)imide, tributylmethylammonium dicyanamide, tributylmethylammonium bis(trifluoromethylsulfonyl)imide, tris(2-hydroxyethyl)methylammonium methylsulfate, 2-hydroxyethyltrimethylammonium acetate, 2-hydroxyethyltrimethylammonium lactate, 2-hydroxyethyltrimethylammonium salicylate, tetrabutylammonium chloride, 1,3-dimethylimidazolium methylsulfate, 1,2,3-trimethylimidazolium methylsulfate, 1-ethyl-3-methylimidazolium acetate, 1-ethyl-3-methylimidazolium dicyanamide, 1-ethyl-3-methylimidazolium methylsulfate, 1-ethyl-3-methylimidazolium thiocyanate, 1-ethyl-2,3-dimethylimidazolium bis(trifluoromethylsulfonyl)imide, 1-propyl-3-methylimidazolium acetate, 1-propyl-3-methylimidazolium bis(trifluoromethylsulfonyl)imide, 1-propyl-2,3-dimethylimidazolium bis(trifluoromethylsulfonyl)imide, 1-butyl-3-methylimidazolium acetate, 1-butyl-3-methylimidazolium dicyanamide, 1-butyl-3-methylimidazolium thiocyanate, 1-butyl-3-methylimidazolium bromide, 1-butyl-3-methylimidazolium hexafluorophosphate, 1-butyl-3-methylimidazolium tetrafluoroborate, 1-butyl-2,3-dimethylimidazolium bis(trifluoromethylsulfonyl)imide, 1-octyl-3-methylimidazolium acetate, 1-octyl-3-methylimidazolium bromide, 1-octyl-3-methylimidazolium tetrafluoroborate, 1-methyl-1-butylpyrrolidinium dicyanamide, 1-methyl-1-octylpyrrolidinium bis(trifluoromethylsulfonyl)imide, 1-methyl-1-butylpiperidinium bis(trifluoromethylsulfonyl)imide, 1-ethyl-3-methylpyridinium ethylsulfate, 1-butyl-4-methylpyridinium bis(trifluoromethylsulfonyl)imide and 1-butylpyridinium tetrafluoroborate. In a more preferred embodiment, the ionic liquid has an imidazolium type ion as a cation and an acetate as an anion, and exemplified embodiments thereof include 1-ethyl-3-methylimidazolium acetate, 1-propyl-3-methylimidazolium acetate, 1-butyl-3-methylimidazolium acetate and 1-octyl-3-methylimidazolium acetate.

The ionic liquid has catalytic action that promotes the curing of polysiloxane, and it is assumed that the curing can be completed even at a relatively low temperature.

The mixing ratio of the ionic liquid to the polysiloxane (ionic liquid/polysiloxane) is preferably 0.000030 to 0.10, more preferably 0.000050 to 0.10, further preferably 0.00010 to 0.10 in terms of mass ratio. This is because, due to being in such a range, the effect of low temperature curing is more exhibited and the density of the cured film tends to be increased.

Further, since the ionic liquid can be uniformly present in the composition as compared with the commonly used curing accelerator (for example, a thermal base generator), it is assumed that the ionic liquid exhibits effects on suppressing voids.

The ionic liquid can be used alone or in combination of two or more of any of these. The content of the ionic liquid is preferably 0.00020 to 4.0 mass %, more preferably 0.00020 to 3.2 mass %, based on the total mass of the composition according to the present invention.

### Acid

The underlayer composition according to the present invention can contain an acid.

The acid may be an inorganic acid or an organic acid, but is preferably an organic acid, more preferably a carboxylic acid, further preferably a monocarboxylic acid or a dicarboxylic acid, further more preferably a dicarboxylic acid.

Examples of the monocarboxylic acid include acetic acid, formic acid, propionic acid, butyric acid, valeric acid and acrylic acid, and acetic acid is preferable.

Examples of the dicarboxylic acid include oxalic acid, maleic acid, fumaric acid, phthalic acid, succinic acid, glutaconic acid, aspartic acid, glutamic acid, malic acid, citraconic acid, acetylenedicarboxylic acid, itaconic acid, mesaconic acid, 3-aminohexandioic acid and malonic acid, preferably oxalic acid, maleic acid, fumaric acid, phthalic acid, succinic acid, malic acid, citraconic acid, acetylenedicarboxylic acid or malonic acid, further preferably oxalic acid, maleic acid, fumaric acid, phthalic acid, citraconic acid or acetylenedicarboxylic acid.

It is preferable that the acid has high sublimability, which is to sublimate when heated for curing. In particular, the sublimation temperature is preferably 90 to 300° C., more preferably 90 to 250° C. This is because the residual amount of the cured film is reduced by the sublimation of the acid when the coating film is cured.

Although not wishing to be bound by theory, as described above, the ionic liquid functions as a catalyst that accelerates the curing of polysiloxane at a low temperature. With respect to the composition comprising an ionic liquid, a polysiloxane and a solvent, there is a case that curing is proceeded even during long-term storage at room temperature, resulting in gelation or the like. On the other hand, it is assumed that by combining an acid, it is possible to suppress the catalytic action of the ionic liquid and exhibit sufficient storage stability. It is assumed that the sublimation of the acid during heating for curing makes the catalytic action of the ionic liquid be exhibited so that it's possible to cure at a low temperature. In order to exhibit better storage stability and low temperature curability, the present invention preferably comprises a combination of an ionic liquid and a carboxylic acid, more preferably a combination of an ionic liquid and oxalic acid, maleic acid, fumaric acid, phthalic acid, citraconic acid or acetylenedicarboxylic acid, further preferably a combination of an ionic liquid in which the cation is an imidazolium type ion and the anion is an acetate ion, and maleic acid.

In a preferred embodiment, exemplified embodiments of the combination of the ionic liquid and the acid (ionic liquid/acid) include tributylmethylammonium dicyanamide/acetic acid, tris(2-hydroxyethyl)methylammonium methyl sulfate/acetic acid, 2-hydroxyethyltrimethylammonium acetate/acetic acid, 2-hydroxyethyltrimethylammonium lactate/acetic acid, 2-hydroxyethyltrimethylammonium salicylate/acetic acid, tetrabutylammonium chloride/acetic acid, 1-ethyl-3-methylimidazolium acetate/acetic acid, 1-ethyl-3-methylimidazolium dicyanamide/acetic acid, 1-ethyl-3-methylimidazolium methyl sulfate/acetic acid, 1-ethyl-3-methylimidazolium thiocyanate/acetic acid, 1-propyl-3-methylimidazolium acetate/acetic acid, 1-butyl-3-methylimidazolium acetate/acetic acid, 1-butyl-3-methylimidazolium dicyanamide/acetic acid, 1-butyl-3-methylimidazolium thiocyanate/acetic acid, 1-butyl-3-methylimidazolium bromide/acetic acid, 1-octyl-3-methylimidazolium acetate/acetic acid, 1-octyl-3-methylimidazolium bromide/acetic acid, tributylmethylammonium dicyanamide/succinic acid, tris(2-hydroxyethyl)methylammonium methyl sulfate/succinic acid, 2-hydroxyethyltrimethylammonium acetate/succinic acid, 2-hydroxyethyltrimethylammonium lactate/succinic acid, 2-hydroxyethyltrimethylammonium salicylate/succinic acid, tetrabutylammonium chloride/succinic acid, 1-ethyl-3-methylimidazolium acetate/succinic acid, 1-ethyl-3-methylimidazolium dicyanamide/succinic acid, 1-ethyl-3-methylimidazolium methyl sulfate/succinic acid, 1-ethyl-3-methylimidazolium thiocyanate/succinic acid, 1-propyl-3-methylimidazolium acetate/succinic acid, 1-butyl-3-methylimidazolium acetate/succinic acid, 1-butyl-3-methylimidazolium dicyanamide/succinic acid, 1-butyl-3-methylimidazolium thiocyanate/succinic acid, 1-butyl-3-methylimidazolium bromide/succinic acid, 1-octyl-3-methylimidazolium acetate/succinic acid, 1-octyl-3-methylimidazolium bromide/succinic acid, 1-methyl-1-butylpyrrolidinium dicyanamide/succinic acid, tributylmethylammonium dicyanamide/glutaconic acid, tris(2-hydroxyethyl)methylammonium methyl sulfate/glutaconic acid, 2-hydroxyethyltrimethylammonium acetate/glutaconic acid, 2-hydroxyethyltrimethylammonium lactate/glutaconic acid, 2-hydroxyethyltrimethylammonium salicylate/glutaconic acid, tetrabutylammonium chloride/glutaconic acid, 1-ethyl-3-methylimidazolium acetate/glutaconic acid, 1-ethyl-3-methylimidazolium dicyanamide/glutaconic acid, 1-ethyl-3-methylimidazolium methyl sulfate/glutaconic acid, 1-ethyl-3-methylimidazolium thiocyanate/glutaconic acid, 1-propyl-3-methylimidazolium acetate/glutaconic acid, 1-butyl-3-methylimidazolium acetate/glutaconic acid, 1-butyl-3-methylimidazolium dicyanamide/glutaconic acid, 1-butyl-3-methylimidazolium thiocyanate/glutaconic acid, 1-butyl-3-methylimidazolium bromide/glutaconic acid, 1-octyl-3-methylimidazolium acetate/glutaconic acid, 1-octyl-3-methylimidazolium bromide/glutaconic acid, trimethylbutylammonium bis(trifluoromethylsulfonyl)imide/citraconic acid, tributylmethylammonium dicyanamide/citraconic acid, tributylmethylammonium bis(trifluoromethylsulfonyl)imide/citraconic acid, tris(2-hydroxyethyl)methylammonium methyl sulfate/citraconic acid, 2-hydroxyethyltrimethylammonium acetate/citraconic acid, 2-hydroxyethyltrimethylammonium lactate/citraconic acid, 2-hydroxyethyltrimethylammonium salicylate/citraconic acid, tetrabutylammonium chloride/citraconic acid, 1,3-dimethylimidazolium methyl sulfate/citraconic acid, 1,2,3-trimethylimidazolium methyl sulfate/citraconic acid, 1-ethyl-3-methylimidazolium acetate/citraconic acid, 1-ethyl-3-methylimidazolium dicyanamide/citraconic acid, 1-ethyl-3-methylimidazolium methyl sulfate/citraconic acid, 1-ethyl-3-methylimidazolium thiocyanate/citraconic acid, 1-propyl-3-methylimidazolium acetate/citraconic acid, 1-propyl-3-methylimidazolium bis(trifluoromethylsulfonyl)imide/citraconic acid, 1-butyl-3-methylimidazolium acetate/citraconic acid, 1-butyl-3-methylimidazolium dicyanamide/citraconic acid, 1-butyl-3-methylimidazolium thiocyanate/citraconic acid, 1-butyl-3-methylimidazolium bromide/citraconic acid, 1-butyl-3-methylimidazolium hexafluorophosphate/citraconic acid, 1-butyl-3-methylimidazolium tetrafluoroborate/citraconic acid, 1-octyl-3-methylimidazolium acetate/citraconic acid, 1-octyl-3-methylimidazolium bromide/citraconic acid, 1-octyl-3-methylimidazolium tetrafluoroborate/citraconic acid, 1-methyl-1-butylpyrrolidinium dicyanamide/citraconic acid, 1-methyl-1-octylpyrrolidinium bis(trifluoromethylsulfonyl)imide/citraconic acid, 1-methyl-1-butylpiperidinium bis(trifluoromethylsulfonyl)imide/citraconic acid, 1-ethyl-3-methylpyridinium ethyl sulfate/citraconic acid, 1-butyl-4-methylpyridinium bis(trifluoromethylsulfonyl)imide/citraconic acid, 1-butylpyridinium tetrafluoroborate/citraconic acid, trimethylbutylammonium bis(trifluoromethylsulfonyl)imide/acetylenedicarboxylic acid, tributylmethylammonium dicyanamide/acetylenedicarboxylic acid, tributylmethylammonium bis(trifluoromethylsulfonyl)imide/acetylenedicarboxylic acid, tris(2-hydroxyethyl)methylammonium methyl sulfate/acetylenedicarboxylic acid, 2-hydroxyethyltrimethylammonium acetate/acetylenedicarboxylic acid, 2-hydroxyethyltrimethylammonium lactate/acetylenedicarboxylic acid, 2-hydroxyethyltrimethylammonium salicylate/acetylenedicarboxylic acid, tetrabutylammonium chloride/acetylenedicarboxylic acid, 1,3-dimethylimidazolium methyl sulfate/acetylenedicarboxylic acid, 1,2,3-trimethylimidazolium methyl sulfate/acetylenedicarboxylic acid, 1-ethyl-3-methylimidazolium acetate/acetylenedicarboxylic acid, 1-ethyl-3-methylimidazolium dicyanamide/acetylenedicarboxylic acid, 1-ethyl-3-methylimidazolium methyl sulfate/acetylenedicarboxylic acid, 1-ethyl-3-methylimidazolium thiocyanate/acetylenedicarboxylic acid, 1-propyl-3-methylimidazolium acetate/acetylenedicarboxylic acid, 1-propyl-3-methylimidazolium bis(trifluoromethylsulfonyl)imide/acetylenedicarboxylic acid, 1-butyl-3-methylimidazolium acetate/acetylenedicarboxylic acid, 1-butyl-3-methylimidazolium dicyanamide/acetylenedicarboxylic acid, 1-butyl-3-methylimidazolium thiocyanate/acetylenedicarboxylic acid, 1-butyl-3-methylimidazolium bromide/acetylenedicarboxylic acid, 1-butyl-3-methylimidazolium hexafluorophosphate/acetylenedicarboxylic acid, 1-butyl-3-methylimidazolium tetrafluoroborate/acetylenedicarboxylic acid, 1-octyl-3-methylimidazolium acetate/acetylenedicarboxylic acid, 1-octyl-3-methylimidazolium bromide/acetylenedicarboxylic acid, 1-octyl-3-methylimidazolium tetrafluoroborate/acetylenedicarboxylic acid, 1-methyl-1-butylpyrrolidinium dicyanamide/acetylenedicarboxylic acid, 1-methyl-1-octylpyrrolidinium bis(trifluoromethylsulfonyl)imide/acetylenedicarboxylic acid, 1-methyl-1-butylpiperidinium bis(trifluoromethylsulfonyl)imide/acetylenedicarboxylic acid, 1-ethyl-3-methylpyridinium ethyl sulfate/acetylenedicarboxylic acid, 1-butyl-4-methylpyridinium bis(trifluoromethylsulfonyl)imide/acetylenedicarboxylic acid, 1-butylpyridinium tetrafluoroborate/acetylenedicarboxylic acid, trimethylbutylammonium bis(trifluoromethylsulfonyl)imide/oxalic acid, tributylmethylammonium dicyanamide/oxalic acid, tributylmethylammonium bis(trifluoromethylsulfonyl)imide/oxalic acid, tris(2-hydroxyethyl)methylammonium methyl sulfate/oxalic acid, 2-hydroxyethyltrimethylammonium acetate/oxalic acid, 2-hydroxyethyltrimethylammonium lactate/oxalic acid, 2-hydroxyethyltrimethylammonium salicylate/oxalic acid, tetrabutylammonium chloride/oxalic acid, 1,3-dimethylimidazolium methyl sulfate/oxalic acid, 1,2,3-trimethylimidazolium methyl sulfate/oxalic acid, 1-ethyl-3-methylimidazolium acetate/oxalic acid, 1-ethyl-3-methylimidazolium dicyanamide/oxalic acid, 1-ethyl-3-methylimidazolium methyl sulfate/oxalic acid, 1-ethyl-3-methylimidazolium thiocyanate/oxalic acid, 1-propyl-3-methylimidazolium acetate/oxalic acid, 1-propyl-3-methylimidazolium bis(trifluoromethylsulfonyl)imide/oxalic acid, 1-butyl-3-methylimidazolium acetate/oxalic acid, 1-butyl-3-methylimidazolium dicyanamide/oxalic acid, 1-butyl-3-methylimidazolium thiocyanate/oxalic acid, 1-butyl-3-methylimidazolium bromide/oxalic acid, 1-butyl-3-methylimidazolium hexafluorophosphate/oxalic acid, 1-butyl-3-methylimidazolium tetrafluoroborate/oxalic acid, 1-octyl-3-methylimidazolium acetate/oxalic acid, 1-octyl-3-methylimidazolium bromide/oxalic acid, 1-octyl-3-methylimidazolium tetrafluoroborate/oxalic acid, 1-methyl-1-butylpyrrolidinium dicyanamide/oxalic acid, 1-methyl-1-octylpyrrolidinium bis(trifluoromethylsulfonyl)imide/oxalic acid, 1-methyl-1-butylpiperidinium bis(trifluoromethylsulfonyl)imide/oxalic acid, 1-ethyl-3-methylpyridinium ethyl sulfate/oxalic acid, 1-butyl-4-methylpyridinium bis(trifluoromethylsulfonyl)imide/oxalic acid, 1-butylpyridinium tetrafluoroborate/oxalic acid, trimethylbutylammonium bis(trifluoromethylsulfonyl)imide/maleic acid, tributylmethylammonium dicyanamide/maleic acid, tributylmethylammonium acid, tris(2-bis(trifluoromethylsulfonyl)imide/maleic hydroxyethyl)methylammonium methyl sulfate/maleic acid, 2-hydroxyethyltrimethylammonium acetate/maleic acid, 2-hydroxyethyltrimethylammonium lactate/maleic acid, 2-hydroxyethyltrimethylammonium salicylate/maleic acid, tetrabutylammonium chloride/maleic acid, 1,3-dimethylimidazolium methyl sulfate/maleic acid, 1,2,3-trimethylimidazolium methyl sulfate/maleic acid, 1-ethyl-3-methylimidazolium acetate/maleic acid, 1-ethyl-3-methylimidazolium dicyanamide/maleic acid, 1-ethyl-3-methylimidazolium methyl sulfate/maleic acid, 1-ethyl-3-methylimidazolium thiocyanate/maleic acid, 1-propyl-3-methylimidazolium acetate/maleic acid, 1-propyl-3-methylimidazolium bis(trifluoromethylsulfonyl)imide/maleic acid, 1-butyl-3-methylimidazolium acetate/maleic acid, 1-butyl-3-methylimidazolium dicyanamide/maleic acid, 1-butyl-3-methylimidazolium thiocyanate/maleic acid, 1-butyl-3-methylimidazolium bromide/maleic acid, 1-butyl-3-methylimidazolium hexafluorophosphate/maleic acid, 1-butyl-3-methylimidazolium tetrafluoroborate/maleic acid, 1-octyl-3-methylimidazolium acetate/maleic acid, 1-octyl-3-methylimidazolium bromide/maleic acid, 1-octyl-3-methylimidazolium tetrafluoroborate/maleic acid, 1-methyl-1-butylpyrrolidinium dicyanamide/maleic acid, 1-methyl-1-octylpyrrolidinium bis(trifluoromethylsulfonyl)imide/maleic acid, 1-methyl-1-butylpiperidinium bis(trifluoromethylsulfonyl)imide/maleic acid, 1-ethyl-3-methylpyridinium ethyl sulfate/maleic acid, 1-butyl-4-methylpyridinium bis(trifluoromethylsulfonyl)imide/maleic acid, 1-butylpyridinium tetrafluoroborate/maleic acid, trimethylbutylammonium bis(trifluoromethylsulfonyl)imide/fumaric acid, tributylmethylammonium dicyanamide/fumaric acid, tributylmethylammonium acid, tris(2-bis(trifluoromethylsulfonyl)imide/fumaric hydroxyethyl)methylammonium methyl sulfate/fumaric acid, 2-hydroxyethyltrimethylammonium acetate/fumaric acid, 2-hydroxyethyltrimethylammonium lactate/fumaric acid, 2-hydroxyethyltrimethylammonium salicylate/fumaric acid, tetrabutylammonium chloride/fumaric acid, 1,3-dimethylimidazolium methyl sulfate/fumaric acid, 1,2,3-trimethylimidazolium methyl sulfate/fumaric acid, 1-ethyl-3-methylimidazolium acetate/fumaric acid, 1-ethyl-3-methylimidazolium dicyanamide/fumaric acid, 1-ethyl-3-methylimidazolium methyl sulfate/fumaric acid, 1-ethyl-3-methylimidazolium thiocyanate/fumaric acid, 1-propyl-3-methylimidazolium acetate/fumaric acid, 1-propyl-3-methylimidazolium bis(trifluoromethylsulfonyl)imide/fumaric acid, 1-butyl-3-methylimidazolium acetate/fumaric acid, 1-butyl-3-methylimidazolium dicyanamide/fumaric acid, 1-butyl-3-methylimidazolium thiocyanate/fumaric acid, 1-butyl-3-methylimidazolium bromide/fumaric acid, 1-butyl-3-methylimidazolium hexafluorophosphate/fumaric acid, 1-butyl-3-methylimidazolium tetrafluoroborate/fumaric acid, 1-octyl-3-methylimidazolium acetate/fumaric acid, 1-octyl-3-methylimidazolium bromide/fumaric acid, 1-octyl-3-methylimidazolium tetrafluoroborate/fumaric acid, 1-methyl-1-butylpyrrolidinium dicyanamide/fumaric acid, 1-methyl-1-octylpyrrolidinium bis(trifluoromethylsulfonyl)imide/fumaric acid, 1-methyl-1-butylpiperidinium bis(trifluoromethylsulfonyl)imide/fumaric acid, 1-ethyl-3-methylpyridinium ethyl sulfate/fumaric acid, 1-butyl-4-methylpyridinium bis(trifluoromethylsulfonyl)imide/fumaric acid, 1-butylpyridinium tetrafluoroborate/fumaric acid, trimethylbutylammonium bis(trifluoromethylsulfonyl)imide/phthalic acid, tributylmethylammonium dicyanamide/phthalic acid, tributylmethylammonium bis(trifluoromethylsulfonyl)imide/phthalic acid, tris(2-hydroxyethyl)methylammonium methyl sulfate/phthalic acid, 2-hydroxyethyltrimethylammonium acetate/phthalic acid, 2-hydroxyethyltrimethylammonium lactate/phthalic acid, 2-hydroxyethyltrimethylammonium salicylate/phthalic acid, tetrabutylammonium chloride/phthalic acid, 1,3-dimethylimidazolium methyl sulfate/phthalic acid, 1,2,3-trimethylimidazolium methyl sulfate/phthalic acid, 1-ethyl-3-methylimidazolium acetate/phthalic acid, 1-ethyl-3-methylimidazolium dicyanamide/phthalic acid, 1-ethyl-3-methylimidazolium methyl sulfate/phthalic acid, 1-ethyl-3-methylimidazolium thiocyanate/phthalic acid, 1-propyl-3-methylimidazolium acetate/phthalic acid, 1-propyl-3-methylimidazolium bis(trifluoromethylsulfonyl)imide/phthalic acid, 1-butyl-3-methylimidazolium acetate/phthalic acid, 1-butyl-3-methylimidazolium dicyanamide/phthalic acid, 1-butyl-3-methylimidazolium thiocyanate/phthalic acid, 1-butyl-3-methylimidazolium bromide/phthalic acid, 1-butyl-3-methylimidazolium hexafluorophosphate/phthalic acid, 1-butyl-3-methylimidazolium tetrafluoroborate/phthalic acid, 1-octyl-3-methylimidazolium acetate/phthalic acid, 1-octyl-3-methylimidazolium bromide/phthalic acid, 1-octyl-3-methylimidazolium tetrafluoroborate/phthalic acid, 1-methyl-1-butylpyrrolidinium dicyanamide/phthalic acid, 1-methyl-1-octylpyrrolidinium bis(trifluoromethylsulfonyl)imide/phthalic acid, 1-methyl-1-butylpiperidinium bis(trifluoromethylsulfonyl)imide/phthalic acid, 1-ethyl-3-methylpyridinium ethyl sulfate/phthalic acid, 1-butyl-4-methylpyridinium bis(trifluoromethylsulfonyl)imide/phthalic acid, and 1-butylpyridinium tetrafluoroborate/phthalic acid.

In a more preferred embodiment, exemplified embodiments of the combination of the ionic liquid and the acid (ionic liquid/acid) include trimethylbutylammonium bis(trifluoromethylsulfonyl)imide/citraconic acid, tributylmethylammonium dicyanamide/citraconic acid, tributyl methylammonium bis(trifluoromethylsulfonyl)imide/citraconic acid, tris(2-hydroxyethyl)methylammonium methyl sulfate/citraconic acid, 2-hydroxyethyltrimethylammonium acetate/citraconic acid, 2-hydroxyethyltrimethylammonium lactate/citraconic acid, 2-hydroxyethyltrimethylammonium salicylate/citraconic acid, tetrabutylammonium chloride/citraconic acid, 1,3-dimethylimidazolium methyl sulfate/citraconic acid, 1,2,3-trimethylimidazolium methyl sulfate/citraconic acid, 1-ethyl-3-methylimidazolium acetate/citraconic acid, 1-ethyl-3-methylimidazolium dicyanamide/citraconic acid, 1-ethyl-3-methylimidazolium methyl sulfate/citraconic acid, 1-ethyl-3-methylimidazolium thiocyanate/citraconic acid, 1-propyl-3-methylimidazolium acetate/citraconic acid, 1-propyl-3-methylimidazolium bis(trifluoromethylsulfonyl)imide/citraconic acid, 1-butyl-3-methylimidazolium acetate/citraconic acid, 1-butyl-3-methylimidazolium dicyanamide/citraconic acid, 1-butyl-3-methylimidazolium thiocyanate/citraconic acid, 1-butyl-3-methylimidazolium bromide/citraconic acid, 1-butyl-3-methylimidazolium hexafluorophosphate/citraconic acid, 1-butyl-3-methylimidazolium tetrafluoroborate/citraconic acid, 1-octyl-3-methylimidazolium acetate/citraconic acid, 1-octyl-3-methylimidazolium bromide/citraconic acid, 1-octyl-3-methylimidazolium tetrafluoroborate/citraconic acid, 1-methyl-1-butylpyrrolidinium dicyanamide/citraconic acid, 1-methyl-1-octylpyrrolidinium bis(trifluoromethylsulfonyl)imide/citraconic acid, 1-methyl-1-butylpiperidinium bis(trifluoromethylsulfonyl)imide/citraconic acid, 1-ethyl-3-methylpyridinium ethyl sulfate/citraconic acid, 1-butyl-4-methylpyridinium bis(trifluoromethylsulfonyl)imide/citraconic acid, 1-butylpyridinium tetrafluoroborate/citraconic acid, trimethylbutylammonium bis(trifluoromethylsulfonyl)imide/acetylenedicarboxylic acid, tributylmethylammonium dicyanamide/acetylenedicarboxylic acid, tributylmethylammonium bis(trifluoromethylsulfonyl)imide/acetylenedicarboxylic acid, tris(2-hydroxyethyl)methylammonium methyl sulfate/acetylenedicarboxylic acid, 2-hydroxyethyltrimethylammonium acetate/acetylenedicarboxylic acid, 2-hydroxyethyltrimethylammonium lactate/acetylenedicarboxylic acid, 2-hydroxyethyltrimethylammonium salicylate/acetylenedicarboxylic acid, tetrabutylammonium chloride/acetylenedicarboxylic acid, 1,3-dimethylimidazolium methyl sulfate/acetylenedicarboxylic acid, 1,2,3-trimethylimidazolium methyl sulfate/acetylenedicarboxylic acid, 1-ethyl-3-methylimidazolium acetate/acetylenedicarboxylic acid, 1-ethyl-3-methylimidazolium dicyanamide/acetylenedicarboxylic acid, 1-ethyl-3-methylimidazolium methyl sulfate/citraconic acid, 1-ethyl-3-methylimidazolium thiocyanate/acetylenedicarboxylic acid, 1-propyl-3-methylimidazolium acetate/acetylenedicarboxylic acid, 1-propyl-3-methylimidazolium bis(trifluoromethylsulfonyl)imide/acetylenedicarboxylic acid, 1-butyl-3-methylimidazolium acetate/acetylenedicarboxylic acid, 1-butyl-3-methylimidazolium dicyanamide/acetylenedicarboxylic acid, 1-butyl-3-methylimidazolium thiocyanate/acetylenedicarboxylic acid, 1-butyl-3-methylimidazolium bromide/acetylenedicarboxylic acid, 1-butyl-3-methylimidazolium hexafluorophosphate/acetylenedicarboxylic acid, 1-butyl-3-methylimidazolium tetrafluoroborate/acetylenedicarboxylic acid, 1-octyl-3-methylimidazolium acetate/acetylenedicarboxylic acid, 1-octyl-3-methylimidazolium bromide/acetylenedicarboxylic acid, 1-octyl-3-methylimidazolium tetrafluoroborate/acetylenedicarboxylic acid, 1-methyl-1-butylpyrrolidinium dicyanamide/acetylenedicarboxylic acid, 1-methyl-1-octylpyrrolidinium bis(trifluoromethylsulfonyl)imide/acetylenedicarboxylic acid, 1-methyl-1-butylpiperidinium bis(trifluoromethylsulfonyl)imide/acetylenedicarboxylic acid, 1-ethyl-3-methylpyridinium ethyl sulfate/acetylenedicarboxylic acid, 1-butyl-4-methylpyridinium bis(trifluoromethylsulfonyl)imide/acetylenedicarboxylic acid, 1-butylpyridiniumtetrafluoroborate/acetylenedicarboxylic acid, trimethylbutylammonium bis(trifluoromethylsulfonyl)imide/oxalic acid, tributylmethylammonium dicyanamide/oxalic acid, tributylmethylammonium bis(trifluoromethylsulfonyl)imide/oxalic acid, tris(2-hydroxyethyl)methylammonium methyl sulfate/oxalic acid, 2-hydroxyethyltrimethylammonium acetate/oxalic acid, 2-hydroxyethyltrimethylammonium lactate/oxalic acid, 2-hydroxyethyltrimethylammonium salicylate/oxalic acid, tetrabutylammonium chloride/oxalic acid, 1,3-dimethylimidazolium methyl sulfate/oxalic acid, 1,2,3-trimethylimidazolium methyl sulfate/oxalic acid, 1-ethyl-3-methylimidazolium acetate/oxalic acid, 1-ethyl-3-methylimidazolium dicyanamide/oxalic acid, 1-ethyl-3-methylimidazolium methyl sulfate/oxalic acid, 1-ethyl-3-methylimidazolium thiocyanate/oxalic acid, 1-propyl-3-methylimidazolium acetate/oxalic acid, 1-propyl-3-methylimidazolium bis(trifluoromethylsulfonyl)imide/oxalic acid, 1-butyl-3-methylimidazolium acetate/oxalic acid, 1-butyl-3-methylimidazolium dicyanamide/oxalic acid, 1-butyl-3-methylimidazolium thiocyanate/oxalic acid, 1-butyl-3-methylimidazolium bromide/oxalic acid, 1-butyl-3-methylimidazolium hexafluorophosphate/oxalic acid, 1-butyl-3-methylimidazolium tetrafluoroborate/oxalic acid, 1-octyl-3-methylimidazolium acetate/oxalic acid, 1-octyl-3-methylimidazolium bromide/oxalic acid, 1-octyl-3-methylimidazolium tetrafluoroborate/oxalic acid, 1-methyl-1-butylpyrrolidinium dicyanamide/oxalic acid, 1-methyl-1-octylpyrrolidinium bis(trifluoromethylsulfonyl)imide/oxalic acid, 1-methyl-1-butylpiperidinium bis(trifluoromethylsulfonyl)imide/oxalic acid, 1-ethyl-3-methylpyridinium ethyl sulfate/oxalic acid, 1-butyl-4-methylpyridinium bis(trifluoromethylsulfonyl)imide/oxalic acid, 1-butylpyridiniumtetrafluoroborate/oxalic acid, trimethylbutylammonium bis(trifluoromethylsulfonyl)imide/maleic acid, tributylmethylammonium dicyanamide/maleic acid, tributylmethylammonium bis(trifluoromethylsulfonyl)imide/maleic acid, tris(2-hydroxyethyl)methylammonium methyl sulfate/maleic acid, 2-hydroxyethyltrimethylammonium acetate/maleic acid, 2-hydroxyethyltrimethylammonium lactate/maleic acid, 2-hydroxyethyltrimethylammonium salicylate/maleic acid, tetrabutylammonium chloride/maleic acid, 1,3-dimethylimidazolium methyl sulfate/maleic acid, 1,2,3-trimethylimidazolium methyl sulfate/maleic acid, 1-ethyl-3-methylimidazolium acetate/maleic acid, 1-ethyl-3-methylimidazolium dicyanamide/maleic acid, 1-ethyl-3-methylimidazolium methyl sulfate/maleic acid, 1-ethyl-3-methylimidazolium thiocyanate/maleic acid, 1-propyl-3-methylimidazolium acetate/maleic acid, 1-propyl-3-methylimidazolium bis(trifluoromethylsulfonyl)imide/maleic acid, 1-butyl-3-methylimidazolium acetate/maleic acid, 1-butyl-3-methylimidazolium dicyanamide/maleic acid, 1-butyl-3-methylimidazolium thiocyanate/maleic acid, 1-butyl-3-methylimidazolium bromide/maleic acid, 1-butyl-3-methylimidazolium hexafluorophosphate/maleic acid, 1-butyl-3-methylimidazolium tetrafluoroborate/maleic acid, 1-octyl-3-methylimidazolium acetate/maleic acid, 1-octyl-3-methylimidazolium bromide/maleic acid, 1-octyl-3-methylimidazolium tetrafluoroborate/maleic acid, 1-methyl-1-butylpyrrolidinium dicyanamide/maleic acid, 1-methyl-1-octylpyrrolidinium bis(trifluoromethylsulfonyl)imide/maleic acid, 1-methyl-1-butylpiperidinium bis(trifluoromethylsulfonyl)imide/maleic acid, 1-ethyl-3-methylpyridinium ethyl sulfate/maleic acid, 1-butyl-4-methylpyridinium bis(trifluoromethylsulfonyl)imide/maleic 1-acid, butylpyridiniumtetrafluoroborate/maleic acid, trimethylbutylammonium bis(trifluoromethylsulfonyl)imide/fumaric acid, tributylmethylammonium dicyanamide/fumaric acid, tributylmethylammonium acid, tris(2-bis(trifluoromethylsulfonyl)imide/fumaric hydroxyethyl)methylammonium methyl sulfate/fumaric acid, 2-hydroxyethyltrimethylammonium acetate/fumaric acid, 2-hydroxyethyltrimethylammonium lactate/fumaric acid, 2-hydroxyethyltrimethylammonium salicylate/fumaric acid, tetrabutylammonium chloride/fumaric acid, 1,3-dimethylimidazolium methyl sulfate/fumaric acid, 1,2,3-trimethylimidazolium methyl sulfate/fumaric acid, 1-ethyl-3-methylimidazolium acetate/fumaric acid, 1-ethyl-3-methylimidazolium dicyanamide/fumaric acid, 1-ethyl-3-methylimidazolium methyl sulfate/fumaric acid, 1-ethyl-3-methylimidazolium thiocyanate/fumaric acid, 1-propyl-3-methylimidazolium acetate/fumaric acid, 1-propyl-3-methylimidazolium bis(trifluoromethylsulfonyl)imide/fumaric acid, 1-butyl-3-methylimidazolium acetate/fumaric acid, 1-butyl-3-methylimidazolium dicyanamide/fumaric acid, 1-butyl-3-methylimidazolium thiocyanate/fumaric acid, 1-butyl-3-methylimidazolium bromide/fumaric acid, 1-butyl-3-methylimidazolium hexafluorophosphate/fumaric acid, 1-butyl-3-methylimidazolium tetrafluoroborate/fumaric acid, 1-octyl-3-methylimidazolium acetate/fumaric acid, 1-octyl-3-methylimidazolium bromide/fumaric acid, 1-octyl-3-methylimidazolium tetrafluoroborate/fumaric acid, 1-methyl-1-butylpyrrolidinium dicyanamide/fumaric acid, 1-methyl-1-octylpyrrolidinium bis(trifluoromethylsulfonyl)imide/fumaric acid, 1-methyl-1-butylpiperidinium bis(trifluoromethylsulfonyl)imide/fumaric acid, 1-ethyl-3-methylpyridinium ethyl sulfate/fumaric acid, 1-butyl-4-methylpyridinium acid, 1-bis(trifluoromethylsulfonyl)imide/fumaric butylpyridiniumtetrafluoroborate/fumaric acid, trimethylbutylammonium bis(trifluoromethylsulfonyl)imide/phthalic acid, tributylmethylammonium dicyanamide/phthalic acid, tributylmethylammonium acid, tris(2-bis(trifluoromethylsulfonyl)imide/phthalic hydroxyethyl)methylammonium methyl sulfate/phthalic acid, 2-hydroxyethyltrimethylammonium acetate/phthalic acid, 2-hydroxyethyltrimethylammonium lactate/phthalic acid, 2-hydroxyethyltrimethylammonium salicylate/phthalic acid, tetrabutylammonium chloride/phthalic acid, 1,3-dimethylimidazolium methyl sulfate/phthalic acid, 1,2,3-trimethylimidazolium methyl sulfate/phthalic acid, 1-ethyl-3-methylimidazolium acetate/phthalic acid, 1-ethyl-3-methylimidazolium dicyanamide/phthalic acid, 1-ethyl-3-methylimidazolium methyl sulfate/phthalic acid, 1-ethyl-3-methylimidazolium thiocyanate/phthalic acid, 1-propyl-3-methylimidazolium acetate/phthalic acid, 1-propyl-3-methylimidazolium bis(trifluoromethylsulfonyl)imide/phthalic acid, 1-butyl-3-methylimidazolium acetate/phthalic acid, 1-butyl-3-methylimidazolium dicyanamide/phthalic acid, 1-butyl-3-methylimidazolium thiocyanate/phthalic acid, 1-butyl-3-methylimidazolium bromide/phthalic acid, 1-butyl-3-methylimidazolium hexafluorophosphate/phthalic acid, 1-butyl-3-methylimidazolium tetrafluoroborate/phthalic acid, 1-octyl-3-methylimidazolium acetate/phthalic acid, 1-octyl-3-methylimidazolium bromide/phthalic acid, 1-octyl-3-methylimidazolium tetrafluoroborate/phthalic acid, 1-methyl-1-butylpyrrolidinium dicyanamide/phthalic acid, 1-methyl-1-octylpyrrolidinium bis(trifluoromethylsulfonyl)imide/phthalic acid, 1-methyl-1-butylpiperidinium bis(trifluoromethylsulfonyl)imide/phthalic acid, 1-ethyl-3-methylpyridinium ethyl sulfate/phthalic acid, 1-butyl-4-methylpyridinium bis(trifluoromethylsulfonyl)imide/phthalic acid, and 1-butylpyridiniumtetrafluoroborate/phthalic acid.

In a further more preferable embodiment, exemplified embodiments of the combination of the ionic liquid and the acid (ionic liquid/acid) include 1-ethyl-3-methylimidazolium acetate/maleic acid, 1-propyl-3-methylimidazolium acetate/maleic acid, 1-butyl-3-methylimidazolium acetate/maleic acid, and 1-octyl-3-methylimidazolium acetate/maleic acid.

The mixing ratio of the ionic liquid to the acid (ionic liquid/acid) is preferably 0.10 to 1.0, more preferably 0.20 to 1.0, at an equivalent ratio. This is because when the equivalent ratio is less than 0.10, the density of the cured film tends to decrease, and when it exceeds 1.0, the storage stability tends to decrease.

The acid can be used alone or in combination of two or more of any of these. The content of the acid is preferably 0.00020 to 10.0 mass %, more preferably 0.020 to 10.0 mass %, further preferably 0.020 to 8.0 mass %, based on the total mass of the composition according to the present invention.

In the underlayer composition according to the present invention, further compounds can be optionally combined. The materials that can be combined are as described below. The total amount of the components other than those described above in the entire composition is preferably 10% or less, and more preferably 5% or less, based on the total mass of the composition. It is also a preferred embodiment of the present invention to contain no component other than those described above.

Examples of other additives include a surfactant, an adhesion enhancer, an antifoaming agent, a heat curing accelerator and the like.

### Method for Manufacturing Metal Oxide Resist Film

A method for manufacturing a metal oxide resist film according to the present invention includes the following steps:
(a) applying the underlayer composition according to the present invention above a substrate to form a metal oxide resist underlayer;
(b) irradiating the metal oxide resist underlayer with the energy ray; and
(c) forming a metal oxide resist film above the metal oxide resist underlayer irradiated with the energy ray.

### Step (a)

Examples of the substrate include a silicon/silicon dioxide coated substrate, a silicon nitride substrate, a silicon wafer substrate, a glass substrate, and an ITO substrate, and the underlayer composition is applied above the substrate by an appropriate method to form a metal oxide resist underlayer.

Here, in the present invention, the “above a substrate” includes a case where a film is formed immediately above a substrate and a case where a film is formed above a substrate via another layer. For example, an organic film be formed immediately above a substrate, and the underlayer composition according to the present invention may be applied immediately above an SOC film. In a preferred embodiment, an organic film is formed under the metal oxide resist underlayer (including the cases of forming the organic film immediately below the metal oxide resist underlayer and under the metal oxide resist underlayer via another layer), more preferably an organic film (more preferably an SOC film) is formed immediately below the metal oxide resist underlayer.

The application method is not particularly limited, and examples thereof include a coating method using a spinner or a coater. After the coating, an underlayer is formed by heating (prebaking). The prebaking of the underlayer is performed, for example, by a hot plate. The heating temperature is preferably 80 to 200° C. (more preferably 100 to 180° C.; further preferably 120 to 180° C.). The heating time is preferably 30 to 300 seconds.

### Step (b)

The energy ray with which the metal oxide resist underlayer is irradiated is preferably ultraviolet ray preferably having a peak wavelength of 200 nm or less, more preferably having a peak wavelength of 150 to 200 nm. The irradiation amount of the energy ray is preferably 150 to 500 mJ/cm², more preferably 200 to 450 mJ/cm².

After the irradiation with the energy ray in the step (b), it is preferable to further include a step of further heating the metal oxide resist underlayer at 200 to 500° C. (preferably 200 to 450° C.). The polysiloxane is cured by this heating. In a preferred embodiment, heating for this curing is performed at 200 to 250° C. The heating time is preferably 30 seconds to 30 minutes, more preferably 30 seconds to 15 minutes. The film thickness of the metal oxide resist underlayer is preferably 0.5 to 50 nm, more preferably 1 to 30 nm, further preferably 3 to 15 nm.

### Step (c)

After the step (b), if necessary, after the heating step for curing, a metal oxide resist film is formed above the metal oxide resist underlayer. Preferably, a metal oxide resist film is formed immediately above the metal oxide resist underlayer.

The method for applying the resist composition is not particularly limited, but may be the same as the above application, and a vapor phase deposition method is also possible. As a more preferred embodiment, a coating method is exemplified. The metal oxide resist composition is preferably prebaked after being applied. The heating temperature of the prebaking is preferably 75 to 200° C. (more preferably 80 to 180° C.). The heating time is preferably 30 to 240 seconds (more preferably 90 to 180 seconds). The heating is preferably performed in an air or a nitrogen gas atmosphere.

The film thickness of the resist film is preferably 10 to 70 nm (more preferably 10 to 50 nm, further preferably 20 to 30 nm).

A method for manufacturing a resist pattern according to the present invention includes the following steps:
forming a metal oxide resist film by the above-mentioned method;
exposing the metal oxide resist film; and
developing the metal oxide resist film.

### Step of Exposing

The resist film is then exposed through a predetermined mask. The wavelength of the light to be used for the exposure is not particularly limited, but it is preferable to expose with light having a wavelength of 13.5 to 248 nm. In particular, KrF excimer laser (wavelength: 248 nm), ArF excimer laser (wavelength: 193 nm), extreme ultraviolet ray (wavelength: 13.5 nm) and the like can be used, and extreme ultraviolet ray is preferable.

After exposure, post exposure bake (PEB) can be performed, as necessary. The temperature for PEB is preferably 100 to 200° C. (more preferably 150 to 190° C.), and the heating time is preferably 30 to 240 seconds (more preferably 90 to 180 seconds).

### Step of Developing

The exposed resist film is developed using a developer to form a resist pattern. Examples of the development include alkali development and organic solvent development, preferably organic solvent development. The developer contains an organic solvent, more preferably is composed of an organic solvent. In the case of the organic solvent development, examples of the developer include a hydrocarbon-based solvent, an ether-based solvent, an ester-based solvent, a ketone-based solvent, and an alcohol-based solvent, preferably an ester-based solvent or a ketone-based solvent. Exemplified embodiments of the developer include 2-heptanone, butyl acetate, and PGMEA.

Subsequently, if necessary, the substrate is further processed to manufacture an electronic device. Known methods can be applied to this further processing. The method for manufacturing an electronic device according to the present invention includes the above-mentioned method for manufacturing a resist film.

The present invention is explained more particularly below with reference to Examples and Comparative Examples, but the present invention is not limited by these Examples and Comparative Examples at all.

Gel permeation chromatography (GPC) is measured using Alliance (trademark) e2695 type high-speed GPC system (Japan Waters K. K.) and Super Multipore HZ—N type GPC column (Tosoh Corporation). The measurement is conducted using monodispersed polystyrene as a standard sample and cyclohexene as a developing solvent, under the measuring conditions of a flow rate of 0.6 ml/min and a column temperature of 40° C., and then mass average molecular weight (hereinafter sometimes referred to as Mw) is calculated as a relative molecular weight to the standard sample.

### Polysiloxanes A to F

Polysiloxanes A to F are obtained by synthesizing the monomers described in Table 1 at the molar ratios described in Table 1. Each Mw is described in Table 1.

TABLE 1

| | Monomer | | | |
|---|---|---|---|---|
| | methyltrimetoxysilane | phenyltrimetoxysilane | tetramethoxysilane | Mw |
| Polysiloxane A | 60 | 40 | 0 | 2,400 |
| Polysiloxane B | 40 | 60 | 0 | 1,800 |
| Polysiloxane C | 80 | 20 | 0 | 2,900 |
| Polysiloxane D | 50 | 40 | 10 | 2,800 |
| Polysiloxane E | 0 | 100 | 0 | 3,000 |
| Polysiloxane F | 70 | 0 | 30 | 2,200 |

### Preparation of Polysiloxane Compositions

Polysiloxane compositions of Examples 1 to 7 and Comparative Example 2 are prepared by mixing 0.5 parts by mass of a polysiloxane shown in Table 2 and 99.5 parts by mass of a solvent PGMEA.

A polysiloxane composition of Example 8 is prepared by mixing 1.0 part by mass of the polysiloxane A, 0.010 parts by mass of 1-ethyl-3-methylimidazolium acetate (EMIMAc) as an ionic liquid, 0.050 parts by mass of maleic acid, and 98.94 parts by mass of a solvent PGMEA.

### Examples 1 to 8 and Comparative Example 2

An SOC forming composition is spin-coated on a silicon wafer, prebaked at 180° C., then heated at 400° C. for curing to obtain an SOC layer having a film thickness of 55 nm.

The composition prepared above is spin-coated on the SOC layer, prebaked at 150° C., then heated at the temperature described in Table 2 for curing, and further subjected to UV irradiation with 172 nm at 250 mJ/cm² to obtain a polysiloxane underlayer. The film thickness of the polysiloxane underlayer is described in Table 2.

An organometallic tin oxyhydroxide resist composition is spin-coated on the polysiloxane underlayer and prebaked at 150° C. to obtain a metal oxide resist layer having a film thickness of 22 nm.

Using an EUV exposer NXE3400 NA 0.33 (ASML), exposure is performed while the exposure amount is changed in a range of 59 to 101 mJ/cm², and then post exposure bake (PEB) is performed at 180° C. Thereafter, development is performed using 2-heptanone as a developer to form a resist pattern.

The exposure amount when a resist pattern having a line and space of 1:1 is formed with a line & space mask with a pitch of 32 nm is described in Table 2.

### Comparative Example 1

In Comparative Example 1, a resist pattern is formed in the same manner as described above, except that a metal oxide resist layer is formed immediately above the SOC layer. Although pattern peeling or pattern collapse is confirmed in the formed pattern, the exposure amount is specified in a portion where there is no pattern peeling or pattern collapse.

TABLE 2

| | | Film | Curing | Exposure |
|---|---|---|---|---|
| | | Thickness | temperature | amount |
| | Polysiloxane | (nm) | (° C.) | (mJ/cm²) |
| Example 1 | Polysiloxane A | 4 | 400 | 65.4 |
| Example 2 | Polysiloxane A | 3.5 | 400 | 68.5 |
| Example 3 | Polysiloxane A | 10 | 400 | 63.3 |
| Example 4 | Polysiloxane B | 5 | 400 | 66.0 |
| Example 5 | Polysiloxane C | 5 | 400 | 68.0 |
| Example 6 | Polysiloxane D | 5 | 400 | 74.0 |
| Example 7 | Polysiloxane E | 6 | 400 | 66.8 |
| Example 8 | Polysiloxane A | 5 | 220 | 65.2 |
| Comparative | — | — | 400 | 96.0※ |
| Example 1 | | | | |
| Comparative | Polysiloxane F | 5 | 400 | 87.9 |
| Example 2 | | | | |

What is claimed is:

1. A method for improving exposure sensitivity of a metal oxide resist comprising the step of:
forming a lower layer of the metal oxide resist using a composition comprising a polysiloxane comprising a repeating unit represented by the following formula (Ia): 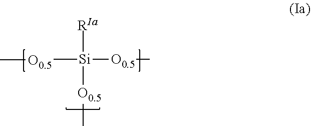
wherein,
R^{Ia} is phenyl, naphthyl, phenalenyl, phenanthrenyl or anthracenyl, which is unsubstituted or substituted with C₁₋₅ alkyl.

2. The method according to claim 1, wherein the polysiloxane further comprises a repeating unit represented by the formula (Ib): 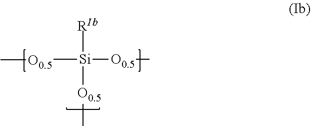
wherein,
R^{Ib} is C₁₋₆ alkyl.

3. The method according to claim 1, wherein the polysiloxane further comprises a repeating unit represented by the formula (Ic):

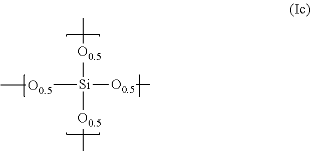

4. The method according to claim 1, wherein the composition is applied above an organic film formed above a substrate to form the metal oxide resist underlayer.

5. The method according to claim 1, wherein the composition further comprises a solvent at a concentration of 90.0 to 99.9 mass % based on the total mass of the composition.

6. A metal oxide resist underlayer composition comprising a polysiloxane comprising repeating units represented by the formula (Ia) and a solvent: 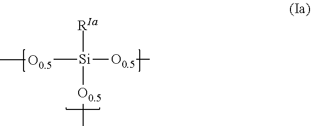
wherein,
R^{Ia} is phenyl, naphthyl, phenalenyl, phenanthrenyl or anthracenyl, which is unsubstituted or substituted with C₁₋₅ alkyl.

7. The composition according to claim 6, wherein the polysiloxane further comprises a repeating unit represented by the formula (Ib): 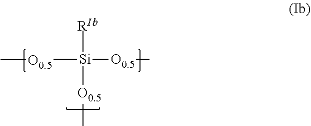
wherein,
R^{Ib} is C₁₋₆ alkyl.

8. The composition according to claim 6, wherein the polysiloxane further comprises a repeating unit represented by the formula (Ic):

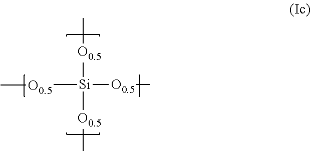

9. The composition according to claim 6, wherein the polysiloxane has a mass average molecular weight of 500 to 20,000.

10. The composition according to claim 6, wherein the solvent is at least one selected from the group consisting of propylene glycol monomethyl ether, 3-methoxybutanol, 1,3-butanediol, propylene glycol monomethyl ether acetate, ethyl lactate, butyl acetate and 3-methoxybutyl acetate.

11. The composition according to claim 6, wherein the content of the solvent is 90.0 to 99.9 mass % based on the total mass of the composition.

12. The composition according to claim 6, further comprising an ionic liquid.

13. A method for manufacturing a metal oxide resist film comprising the following steps:
(a) applying the composition according to claim 6 a substrate to form a metal oxide resist underlayer;
(b) irradiating the metal oxide resist underlayer with the energy ray; and
(c) forming a metal oxide resist film above the metal oxide resist underlayer irradiated with the energy ray.

14. The method according to claim 13, wherein an organic film is formed under the resist underlayer.

15. The method according to claim 13, wherein the energy ray is ultraviolet ray having a peak wavelength of 200 nm or less.

16. The method according to claim 13, wherein the irradiation amount of the energy ray is 150 to 500 mJ/cm².

17. The method according to claim 13, further comprising a step of further heating at 200 to 500° C. after forming the resist underlayer irradiated with the energy ray.

18. A method for manufacturing a resist pattern comprising the following steps:
forming a metal oxide resist film by the method according to claim 13;
exposing the metal oxide resist film; and
developing the metal oxide resist film.

19. A method for manufacturing an electronic device, comprising the method according to claim 13.
